(19) United States
(12) Patent Application Publication
(10) Pub. No.: US 2006/0233233 A1
(43) Pub. Date: Oct. 19, 2006

(54) Method and device for receiving or transmitting a signal with encoded data

(76) Inventors: Matthew L. Welborn, Vienna, VA (US); Michael McLaughlin, Sandyford (IE)

Correspondence Address: POSZ LAW GROUP, PLC, 12040 SOUTH LAKES DRIVE, SUITE 101, RESTON, VA, 20191, US

(21) Appl. No.: 11/077,549

(22) Filed: Mar. 11, 2005

(51) Int. Cl. H03K 9/04; H03K 7/04; H03K 7/06; H03K 9/06

(52) U.S. Cl. 375/239

(57) ABSTRACT

A method of providing encoded data can include receiving a datum. Responsive thereto, the datum can be encoded into a waveform pulse to reflect a position and phase corresponding thereto. A signal can be output with the waveform. A method of demodulating encoded data can include receiving a signal. Responsive thereto, data in the signal can be demodulated to reflect a position and phase of a waveform pulse. Responsive to the pulse and the phase, information represented by the data can be determined. A signal representative of the information can be output. A communication device for transmitting data can include a processor which, responsive to receipt of a datum, can determine a position and phase of a pulse in a waveform corresponding thereto. Responsive thereto, a data stream can be provided representative of the waveform. A transmitter, responsive to receipt of the data stream, can transmit the signal.

### FIELD OF THE INVENTION

The present invention relates in general to wireless communication, and more specifically to transmitters and/or receivers utilizing encoded data.

### BACKGROUND OF THE INVENTION

Wireless communication systems, for example ultra wideband (UWB) systems, are based on the transmission of a signal exhibiting pulses, where the pulses represent the data being transmitted. The signal can be received by a receiver, and the data can be determined by demodulation.

There are two major types of receivers, coherent and non-coherent. Each type of receiver has different advantages and disadvantages.

A receiver can utilize traditional non-coherent demodulation when the exact carrier frequency and/or phase of the signal are not known. However, if the demodulating frequency is slightly different than the modulating frequency the resulting message will be distorted. Non-coherent systems tend to be easier and cheaper to implement, however, they tend to function best with a short range signal.

Unlike non-coherent demodulation, a receiver utilizing coherent demodulation requires knowledge of the transmitted carrier frequency and phase. Such a system can track carrier frequency and phase changes to prevent distortion in the demodulation process. Coherent systems tend to be more sophisticated and more expensive to implement, but are useful with a longer range signal.

The tradeoffs in determining whether to implement a coherent or non-coherent system include performance (e.g., conditions affecting performance) verses complexity (which drives power consumption and hence cost).

A third approach for implementing a receiver now being considered is a differentially coherent system, which attempts to strike a balance between the advantages and disadvantages of the coherent and non-coherent systems.

### BRIEF DESCRIPTION OF THE DRAWINGS

The accompanying FIGURES where like reference numerals refer to identical or functionally similar elements and which together with the detailed description below are incorporated in and form part of the specification, serve to further illustrate an exemplary embodiment and to explain various principles and advantages in accordance with the present invention.

FIG. 1 is a diagram illustrating a simplified and representative devices for transmitting and receiving a signal in a wireless network in accordance with various exemplary embodiments;

FIG. 2 is a block diagram illustrating portions of an exemplary device with wireless transceiver in accordance with various exemplary embodiments;

FIG. 3 is a graph illustrating results for a non-coherent receiver in accordance with various exemplary embodiments;

FIG. 4 is a graph illustrating results for a coherent receiver in accordance with various exemplary embodiments;

FIG. 5 is a graph illustrating results for a non-coherent receiver in accordance with various alternative exemplary embodiments;

FIG. 6 is a graph illustrating results for a coherent receiver in accordance with various alternative exemplary embodiments;

FIG. 7 is a diagram illustrating an exemplary signal in accordance with various exemplary embodiments;

FIG. 8 is a diagram illustrating another exemplary signal in accordance with various exemplary embodiments;

FIG. 9 is a block diagram illustrating encoding of a datum in accordance with various exemplary embodiments;

FIG. 10 is a block diagram illustrating encoding of a datum in accordance with various alternative exemplary embodiments;

FIG. 11 is a diagram illustrating an exemplary signal in accordance with various alternative exemplary embodiments;

FIG. 12 is a flow chart illustrating an exemplary procedure for providing encoded data in accordance with various exemplary and alternative exemplary embodiments; and

FIG. 13 is a flow chart illustrating an exemplary procedure for demodulating encoded data in accordance with various exemplary and alternative exemplary embodiments.

### DETAILED DESCRIPTION

In overview, the present disclosure concerns software, hardware, and/or a combination thereof, and/or components thereof, and the like having a capability to support or being associated with transmitting and/or receiving signals. Such software, hardware, and/or combination, and/or components may be useful in, for example, consumer electronic devices, thermostats, electric lights, low array devices, and the like, for which an ability to transmit and/or receive information is desired, using, for example, an impulse radio transmitter and/or receiver. More particularly, various inventive concepts and principles are embodied in systems, devices, software, and methods therein for receiving or transmitting a signal with encoded data.

The instant disclosure is provided to further explain in an enabling fashion the best modes of performing one or more embodiments of the present invention. The disclosure is further offered to enhance an understanding and appreciation for the inventive principles and advantages thereof, rather than to limit in any manner the invention. The invention is defined solely by the appended claims including any amendments made during the pendency of this application and all equivalents of those claims as issued.

It is further understood that the use of relational terms such as first and second, and the like, if any, are used solely to distinguish one from another entity, item, or action without necessarily requiring or implying any actual such relationship or order between such entities, items or actions. It is noted that some embodiments may include a plurality of processes or steps, which can be performed in any order, unless expressly and necessarily limited to a particular order; i.e., processes or steps that are not so limited may be performed in any order.

Much of the inventive functionality and many of the inventive principles when implemented, are best supported with or in software or integrated circuits (ICs), such as a digital signal processor and software therefore or application specific ICs. It is expected that one of ordinary skill, notwithstanding possibly significant effort and many design choices motivated by, for example, available time, current technology, and economic considerations, when guided by the concepts and principles disclosed herein will be readily capable of generating such software instructions or ICs with minimal experimentation. Therefore, in the interest of brevity and minimization of any risk of obscuring the principles and concepts according to the present invention, further discussion of such software and ICs, if any, will be limited to the essentials with respect to the principles and concepts used by the exemplary embodiments.

As further discussed herein below, various inventive principles and combinations thereof are advantageously employed to provide a signal which can be received by and effectively decoded at different modulation and detection systems.

Further in accordance with exemplary embodiments, there can be provided a basic binary phase shift keying (BPSK) waveform that can support demodulation by either coherent or non-coherent receivers. A non-coherent receiver can use, for example, pulse position modulation (PPM, e.g., 2-PPM) or on-off keying (OOK) demodulation. A coherent receiver can resolve a phase of the pulse and can benefit from an additional coding gain. One or more alternative embodiments can support a differential receiver.

Accordingly, a method and device can provide for encoding data into a waveform not only non-coherently, e.g., for a non-coherent receiver, but also coherently, e.g., for a coherent receiver, with a redundant coded version of the data.

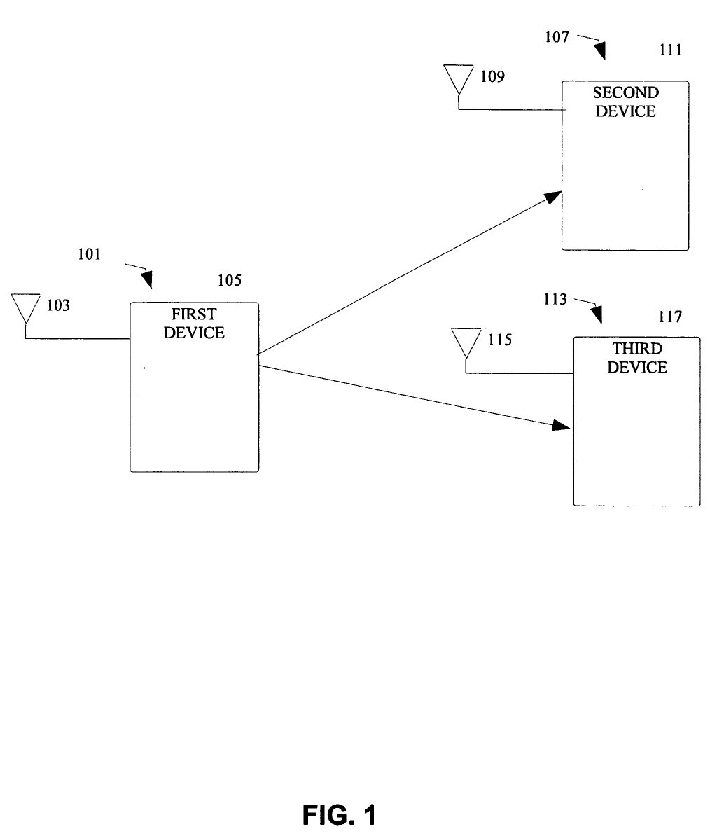

Referring now to FIG. 1, a diagram illustrating simplified and representative communication devices for transmitting and receiving a signal in a wireless network in accordance with various exemplary embodiments will be discussed and described. In this illustration, a first device 101 can transmit a signal to a second device 107 and a third device 113. The first device 101 can transmit the signal from a transmitter 103.

The first device 101 can be provided with a system for encoding data to be transmitted, in accordance with one or more embodiments. Data to be transmitted can be provided in accordance with known techniques for providing such data to be encoded, from conventional internal components in the first device 101. Once the data is encoded, the data can be transmitted over the transmitter 103 as a signal, in accordance with known techniques for causing transmitters to send signals.

The second device 107 and third device 113 can receive the signal at respective receivers, 109, 115. The receiving devices 107, 113 can receive the same signal. In the present example, consider that the second device 107 can be provided with a non-coherent system 111, and the third device 113 can be provided with a coherent system 117.

The first device 101 can provide a signal with the encoded data which can be demodulated by both a non-coherent device, e.g., the second device 107, and a coherent device, e.g., the third device 113. The encoded data in a particular position of a pulse in a waveform can be demodulated by both the non-coherent device and the coherent device, whereas the encoded data in a particular phase of the same pulse in the waveform can be demodulated by the coherent device.

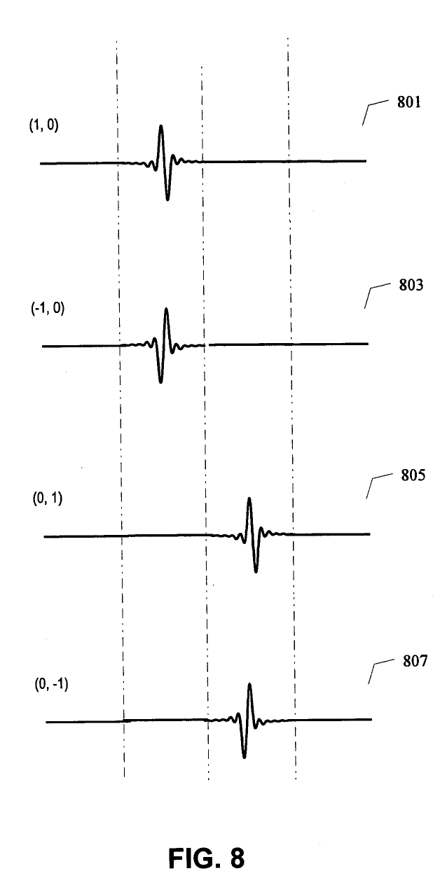

A particular pulse in the waveform of the transmitted signal can be observed to have a particular position and/or a particular phase, both of which are representative of the data. Examples of pulse position and pulse phase are provided below in more detail in connection with FIG. 7 and FIG. 8, respectively. Data can be provided to be encoded as each datum in a bit-wise fashion, where datum is a bit, i.e. “1” or “0;” however, alternative embodiments contemplate that the data is provided byte-wise and/or as an input data stream, or in other modifications.

Accordingly, a method of providing encoded data includes receiving a datum to be encoded. Responsive to the datum, the method provides for encoding the datum into a pulse of a waveform to reflect a position corresponding to the datum, and encoding the datum into the pulse to reflect a phase corresponding to the datum. The method provides for outputting an output signal representative of the waveform.

As shown in the illustration, the first device 101 can transmit the encoded signal over a transmitter 103. Various types of transmitters are appropriate, e.g., an impulse radio transmitter, short wave transmitter, other wireless transmitters, or the like. The transmitter function can be provided in a transceiver, according to one or more embodiments. Accordingly, the method can further comprise transmitting the output signal over a transmitter 103, or preparing the output signal for transmission. In accordance with one or more embodiments, the method is performed in an impulse radio transmitter. The term “impulse radio” as used herein is intended to encompass not only radios conventionally referred to as “impulse radios”, but also bi-phase radios, and the like.

As further illustrated, the second device 107 and/or third device 113 can receive the encoded signal from respective receivers 109, 115. In this example, because the second device 107 includes a standard non-coherent system, it can demodulate the data in accordance with conventional techniques.

The third device 113 can act on the encoded signal which it received in accordance with one or more embodiments. The received signal can be demodulated to determine both position of the pulse in the waveform, and phase of the pulse. The original datum represented by the pulse can therefore be estimated from the received signal; because there is a dual representation of the original datum, the estimation can have enhanced accuracy despite noise which may occur in the signal. Accordingly, there can be provided a method of demodulating encoded data, comprising receiving a signal. The received signal can comprise data representative of a non-coherent waveform and a coherent waveform. Responsive to the received signal, the method can provide for demodulating the data to reflect a position of a pulse of the waveform and a phase of the waveform. Further, the method can provide for determining, responsive to the pulse and the phase, information represented by the data. Also, the method can provide for outputting an output signal representative of the information.

As shown in the illustration, the third device 113 can receive the encoded signal from a receiver 115. Various types of receivers are appropriate, e.g., an impulse radio receiver, short wave radio antenna, other receivers, or the like. The receiver function optionally can be provided in a transceiver. In accordance with one or more embodiments, the method is performed in an impulse radio receiver.

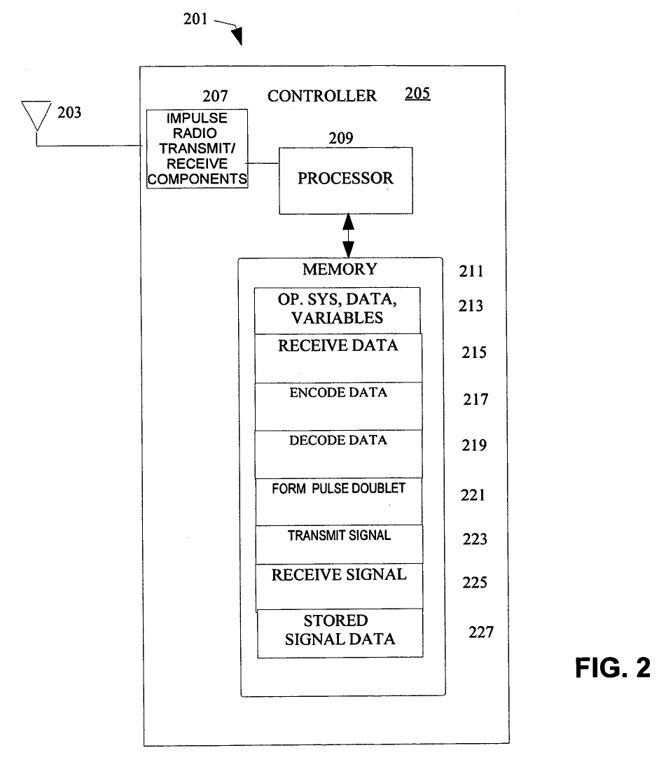

Referring now to FIG. 2, a block diagram illustrating portions of an exemplary communication device with wireless transceiver in accordance with various exemplary embodiments will be discussed and described. The device 201 may include a transceiver 203, a processor 209, a memory 211, and/or impulse radio transmitter/receiver components in-line with the processor 209 and transceiver 203. Many other components that can be included are well understood to those of skill, and are not discussed herein in order for the sake of simplicity.

The processor 209 may comprise one or more microprocessors and/or one or more digital signal processors. The memory 211 may be coupled to the processor 209 and may comprise a read-only memory (ROM), a random-access memory (RAM), a programmable ROM (PROM), and/or an electrically erasable read-only memory (EEPROM). The memory 211 may include multiple memory locations for storing, among other things, an operating system, data and variables 213 for programs executed by the processor 209; computer programs for causing the processor to operate in connection with various functions such as receiving data 215, encoding data 217, decoding data 219, forming a pulse doublet 221, transmitting a signal 223, receiving a signal 225, and/or other processing 1121; and a database or register(s) of information used by the processor 209, such as stored signal data 227. The computer programs may be stored, for example, in ROM or PROM and may direct the processor 209 in controlling the operation of the device 201.

In the illustrated example, the device 201 can be used for both transmitting data and receiving data. Alternative embodiments provide that the device can be equipped for transmitting data or receiving data, and therefore certain functionality can be omitted. Accordingly, the device for transmitting data can comprise a processor 209. The processor 209 can be being configured to facilitate, responsive to receipt of a datum, first determining a position for a pulse in a waveform corresponding to the datum and second determining a phase for the pulse in the waveform corresponding to the datum. Responsive to the first determining and second determining, the device can provide a data stream representative of the waveform having the pulse of the phase in the position to a transmitter. The device can also include a transmitter, responsive to receipt of the data stream, configured to transmit the signal. A decode data 219 process, including the first determining and second determining, is described below.

The processor 209 may be programmed for receiving data 215, where the data represents information that is to be transmitted. The data can be provided in accordance with well-known components, e.g., as output from an A/D converter, as input digital information, or the like. The data that is received can be provided at the desired rate and bit-size, e.g., bit-by-bit, as datum for further processing, such as encoding.

The processor 209 may be programmed for encoding data 217 that is to be transmitted. Based on the datum, a position of a waveform that is to represent the data can be determined, as well as the phase of the waveform. It may be desirable to encode the datum to reflect one or more previous data that were encoded. Accordingly, the stored signal information database 227 can be utilized to determine previous data. Moreover, the process of encoding and/or outputting the output signal can include storing the signal information reflecting the datum to the stored signal information database 227.

The processor 209 may be programmed for decoding data 219 that is received, where the data is provided from a signal, and includes pulses in accordance with one or more embodiments. The data can be demodulated to determine both the position of the pulse in the waveform of the signal, as well as the phase of the pulse. Utilizing both position and phase provides redundancy, so that a better determination of the original data can be provided. Based on the position and the phase, the information represented by the data can be determined, for example using conventional techniques for decoding convolutionally coded data. The decoded information can be output, e.g., as a signal, data stream, output parameters, or the like.

One or more optional embodiments provides that the processor 209 may be programmed for forming a pulse doublet 221 in the output signal, as described in greater detail below in connection with FIG. 11.

The processor 209 may be programmed for transmitting a signal 223. The resulting waveform can exhibit uniformly spaced pulses. For example, an underlying chip-rate clock can be constant. However, as illustrated below, half of the pulses can have a non-zero amplitude. The chip-rate can be selected in accordance with known parameters to allow non-coherent demodulation in a multipath. Once the signal is determined, it can be transmitted from a transmitter in accordance with known techniques.

The processor 209 may be programmed for receiving a signal 225. The signal can be received at a receiver or transceiver 203 in accordance with known techniques. The signal can represent data for both the coherent waveform and the non-coherent waveform, as previously discussed. The received signal can be provided for further processing, e.g., to the process for decoding data 219.

One or more alternative embodiments provides for a further estimation of the information in the received signal, in addition to the initial determination. The additional estimation can utilize position and/or phase. Accordingly, the method of demodulating encoded data can further comprise utilizing at least one of the position and the phase to further estimate the information.

Exemplary alternative embodiments can utilize a differential phase, i.e., that fact that a phase is different from a prior phase, to estimate the information. Accordingly, one or more embodiments further comprise utilizing a differential phase to estimate the information.

Appropriate techniques for providing the estimations include, for example, known Viterbi decoding, maximum a posteriori (MAP) decoding, and the like. Accordingly, one or more embodiments provide that the determining further comprises utilizing Viterbi decoding utilizing at least one of the position, the phase and the differential phase. Accordingly, a further embodiment provides that the determining further comprises utilizing MAP decoding utilizing at least one of the position, the phase and the differential phase.

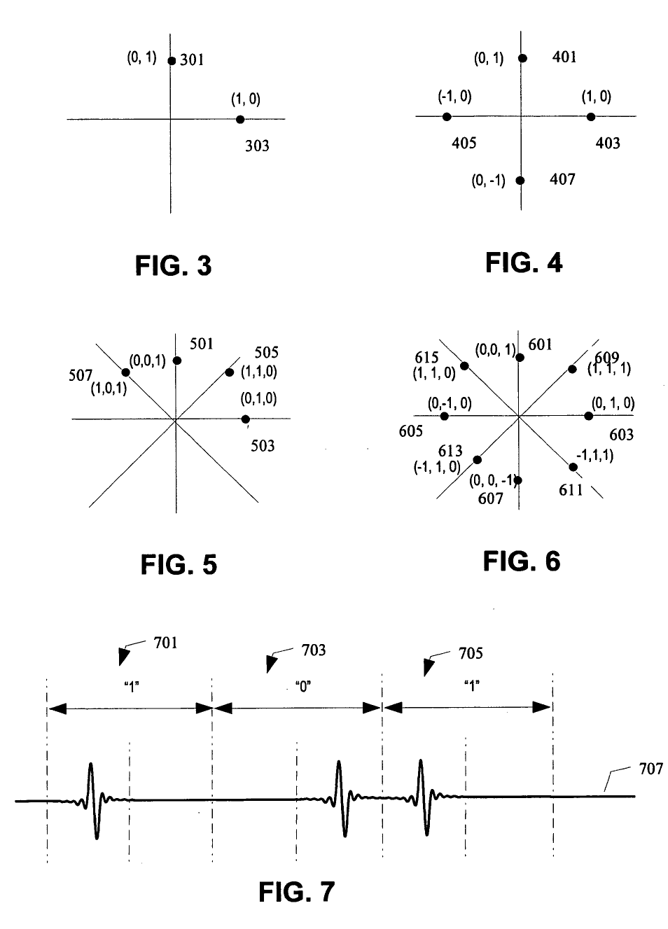

FIG. 3-FIG. 6 provide an illustration contrasting constellations of data points that can be determined by a non-coherent receiver and a coherent receiver. FIG. 3 and FIG. 4 illustrate the difference where the signal utilizes two time slots, and FIG. 5 and 6 illustrate the difference where the signal utilizes more than two time slots or a redundant pulse.

Referring now to FIG. 3, a graph illustrating results for a non-coherent receiver in accordance with various exemplary embodiments will be discussed and described. In this example, there are two time slots where a pulse can occur. A non-coherent receiver can detect the position of the pulse, e.g., whether the pulse occurred in a first time slot in a signal or in a second time slot. The data points illustrated in the constellation represent the first time slot 303 and the second time slot 301. A conventional non-coherent receiver does not have a capability to detect a phase of the pulse. The pulse therefore can convey to a non-coherent receiver one of the two data points. This can be contrasted with FIG. 4, showing the data points that can be conveyed from the same signal to a coherent receiver.

Referring now to FIG. 4, a graph illustrating results for a coherent receiver in accordance with various exemplary embodiments will be discussed and described. A coherent receiver can detect the position and the phase of the pulse. In this example, there are two possible positions. The data points illustrated in the constellation represent the first time slot, first phase 403; second time slot, first phase 401; first time slot, second phase 405; and second time slot, second phase 407. A conventional coherent receiver has a capability to detect a both position and phase of the pulse. The pulse therefore can convey to a coherent receiver one of the four illustrated data points.

FIG. 5 and FIG. 6 illustrate the further information that can be provided when the signal utilizes a redundant pulse or a third time slot, for non-coherent and coherent receivers, respectively. Referring now to FIG. 5, a graph illustrating results for a non-coherent receiver in accordance with various alternative exemplary embodiments will be discussed and described. In this example, there are three time slots where a pulse can occur, or one of the two time slots includes a redundant pulse. There are twice as many possible data points 501, 503, 505, 507 illustrated in this constellation, in comparison to the non-coherent receiver of FIG. 3. Contrast this with FIG. 6, showing the possible data points that can be conveyed from the same signal to a coherent receiver.

Referring now to FIG. 6, a graph illustrating results for a coherent receiver in accordance with various alternative exemplary embodiments will be discussed and described. Because the coherent receiver can detect the position and the phase of the pulse, twice as many data points 601, 603, 605, 607, 609, 611, 613, 615 in the constellation are possible.

FIG. 7 and FIG. 8 provide exemplary signals to further discuss position and phase of pulses, in connection with one or more embodiments.

Referring now to FIG. 7, a diagram illustrating an exemplary signal 707 in accordance with various exemplary embodiments will be discussed and described. The simplified representation of the signal 707 can include first, second and third waveforms 701, 703, 705. Each of the waveforms 701, 703, 705 in this illustration comprises two time slots. Hence, there are two possible positions that can correspond to a datum. The present example illustrates a modulated signal in one time slot of each waveform, i.e., the first position or the second position. The signal can be generated in accordance with one or more embodiments. Pulses which occur in the first position can indicate a “1” datum, and pulses which occur in the second position can indicate a “0” datum, although in certain implementations the reverse could be used. In the present example, the information conveyed by the position of the pulses in the signal 707 is “1” “0” “1”.

The position of the pulses in the signal that is received can be detected in accordance with known techniques. Further, the synchronization of the pulses with the time slots can be determined in accordance with well known techniques.

Referring now to FIG. 8, a diagram illustrating another exemplary signal in accordance with various exemplary embodiments will be discussed and described. Here, first through fourth signals 801, 803, 805, 807 are provided to illustrate possible phases of a waveform. There are two possible phases that can correspond to a datum, first and second phases, where the second phase is a differential of the first phase. The present example illustrates modulated signals with one pulse. This example also illustrates the pulses in particular positions. The signal can be generated in accordance with one or more embodiments. Pulses with the first phase can indicate a “1”, and pulses with a second phase can indicate a “−1” (indicating a reverse phase), corresponding to, e.g., “0” and “1” datum, respectively, although in certain implementations the reverse of “0” and “1” could be used. The pulses in the illustrated first and third signals 801, 805 have the first phase, whereas the pulses in the illustrated second and fourth signals 803, 807 have the second phase.

In addition, each of the pulses occurs in a particular position, where the pulses in the illustrated first and second signals 801, 803 occur in the first position, whereas the pulses in the illustrated third and fourth signals 805, 807 occur in the second position. A coherent receiver can detect both the position and the phase. Accordingly, the information conveyed by the phase and position of the pulses in signals 801, 803, 805 and 807 is (1, 0), (−1, 0), (0, 1) and (0, −1). A non-coherent receiver having received the same signals can detect the position, such that the information conveyed by the position is “1”, “1”, “0”, “0.”

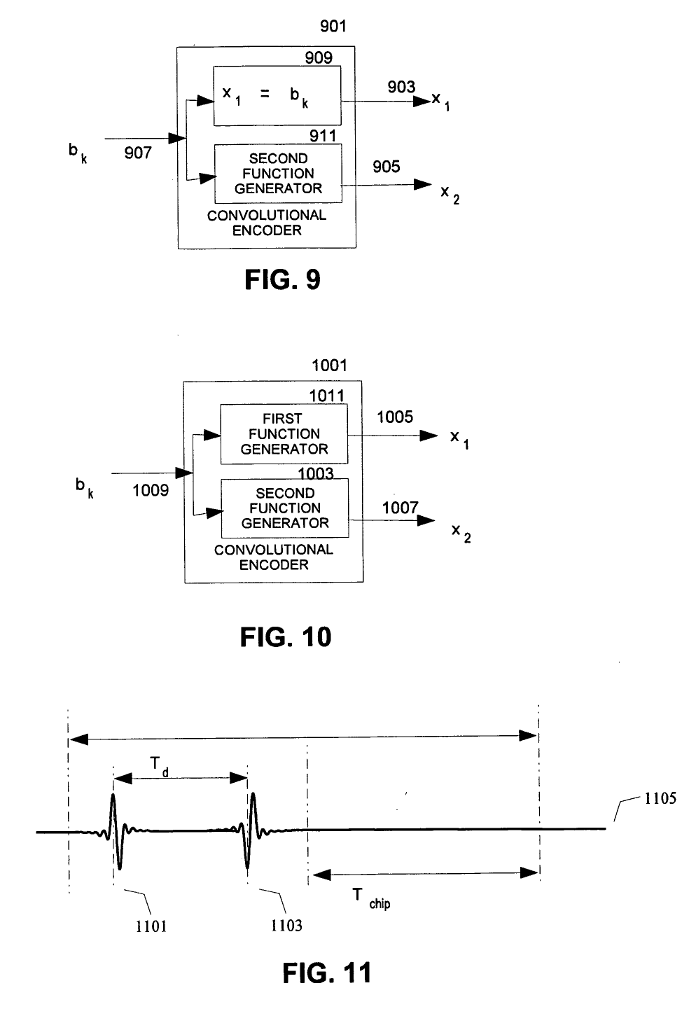

FIG. 9 and FIG. 10 provide illustrations of two exemplary and alternative embodiments for encoding of a datum into a pulse, which can be provided for further processing, e.g., for transmission as a signal.

Referring now to FIG. 9, a block diagram illustrating encoding of a datum in accordance with various exemplary embodiments will be discussed and described. Conventional encoding techniques can be performed on the datum bₖ, where b is the bit and k is the time, in order to provide the position x₁ and the phase x₂ for the pulse. For example, an input signal 907 can be provided to a convolutional encoder 901. The convolutional encoder 901, in this example using a systematic code, can input the datum to a second function generator 911 and provide an output signal 905 indicating the phase x₂ for the pulse. In accordance with one or more embodiments, a function generator 909 can use the datum bₖ directly (as illustrated) as the position x₁ for the pulse. For example, a ½ systematic convolutional code would provide that the first coded bit x₁ is the same as the input data bit bₖ, and the second coded bit x₂ is computed by the convolutional encoder 901. The first coded bit (the systematic bit) can be mapped into, e.g., pulse position modulation (PPM).

In accordance with one or more embodiments, the encoding of the datum bₖ into the pulse to reflect the position further comprises encoding for pulse position modulation. This can be performed to achieve, e.g., a systematic convolutional code, more particularly, a ½ rate systematic convolutional code, a ⅓ rate systematic convolutional code, etc.

In accordance with one or more embodiments, the encoding of the datum into the pulse to reflect the position further comprises encoding for pulse position modulation (PPM) or on-off keying (OOK). Moreover, accordingly, the encoding of the datum into the pulse to reflect the phase can further comprise utilizing a convolutional encoding process. One or more embodiments can provide that the convolutional encoding is systematic.

For example, a device can be provided wherein the processor is further configured to facilitate encoding the datum into the pulse to reflect the phase utilizing a convolutional encoding process. As another example, the device can be provided wherein the processor is further configured to encode the datum into the pulse to reflect the position utilizing encoding for PPM or on-off keying OOK.

In accordance with one or more embodiments, the data can be encoded and/or decoded by a shift register, where the shift register stores prior data values.

Referring now to FIG. 10, a block diagram illustrating encoding of a datum in accordance with various alternative exemplary embodiments will be discussed and described. Here, the encoding of the datum into the pulse reflecting the position utilizes a convolutional encoding process with a general code to compute a redundant bit.

Conventional encoding techniques utilizing the illustrated general code to compute a redundant bit can be performed on the datum bₖ in order to provide the position x₁ and the phase x₂ for the pulse. For example, an input signal 1009 can be provided to a convolutional encoder 1001. The convolutional encoder 1001, in this example using a systematic code, can input the datum to a first function generator 1011 and a second function generator 1003 and provide output signals 1005, 1007 indicating the position x₁ and the phase x₂, respectively, for the pulse.

Referring now to FIG. 11, a diagram illustrating an exemplary signal 1105 in accordance with various alternative exemplary embodiments will be discussed and described. As illustrated, alternative embodiments provide that the waveform can further include at least another pulse, wherein the other pulse is delayed from the first pulse by a pre-determined time. In the present example, the waveform of the signal 1105 includes first pulse 1101 and second pulse 1103. The second pulse 1103 is in the same chip time slot as the first pulse 1101, and is offset from the first pulse 1101 by a time, T_{d}. Note that no pulse occurs in the signal 1105 in the other time slot for the time of the chip time slot T_{chip}. The second pulse 1103 can occur before or after the first pulse 1101. The time offset T_{d} can be pre-determined, and can be the same for a particular transmission.

In the present example, the first pulse 1101 and second pulse 1103 have different phases. A differential phase of the first pulse 1101 and second pulse 1103 can be determined, e.g., by a redundant bit, e.g., x₂ from a convolutional encoding process. After receiving the signal, the receiver device can perform a known coherent demodulation of both pulses in the time slot. Moreover, the signal can be demodulated by a non-coherent receiver decoding for, e.g., PPM or OOK. In addition, the signal can be demodulated by a differential receiving utilizing the time offset T_{d}

A signal with such pulse doublets can be provided, e.g., from a transmitter. Accordingly, one or more embodiments provides a device, wherein the waveform further includes at least another pulse, wherein the processor is further configured to facilitate determining the other pulse including delaying the other pulse from the first pulse by a pre-determined time.

Furthermore, a method can be provided wherein a position of the first pulse and the other pulse is determined by the datum according to a convolutional encoding process. Also, the method can provide that a differential phase of the other pulse is determined by the datum according to a coherent coding process.

Similarly, one or more embodiments can provide a device configured to facilitate decoding the data utilizing the first pulse 1101 and second pulse 1103, e.g., by utilizing the phase differential, and/or utilizing the additional redundant pulse.

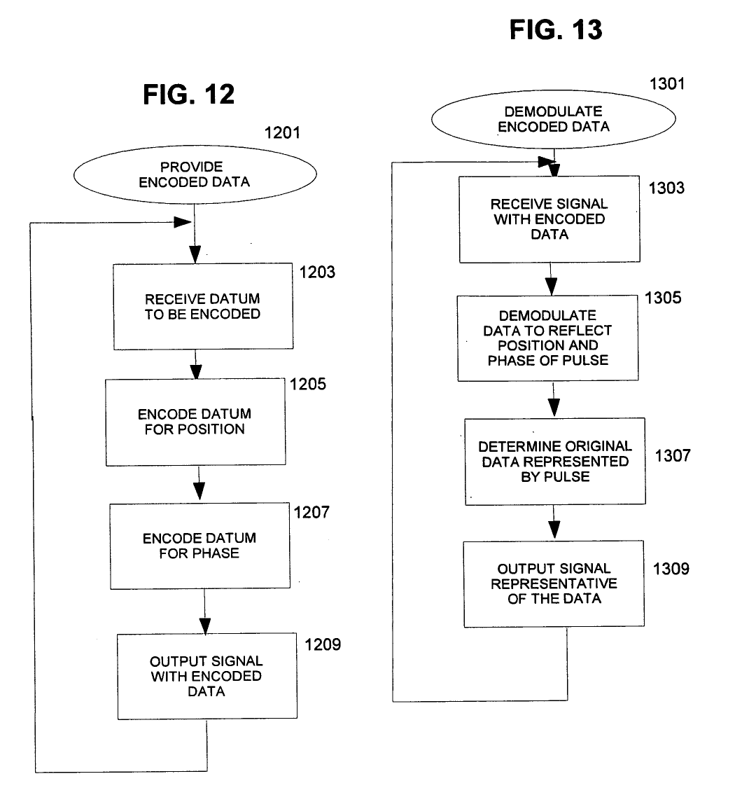

FIG. 12 and FIG. 13 are flow charts illustrating exemplary procedures for providing encoded data, and demodulating the encoded data, respectively.

Referring now to FIG. 12, a flow chart illustrating an exemplary procedure 1201 for providing encoded data in accordance with various exemplary and alternative exemplary embodiments will be discussed and described. The procedure can advantageously be implemented on, for example, a processor of a controller, described in connection with FIG. 2 or other apparatus appropriately arranged. Optionally, the procedure 1201 for providing encoded data can be implemented for example, on a processor of a controller which also includes a procedure for demodulating the encoded data (illustrated in FIG. 13).

In overview, the procedure 1201 for providing encoded data, according to one or more embodiments, can include receiving a datum to be encoded 1203, encoding the datum for position 1205, encoding the datum for phase 1207, and outputting a signal with the encoded data 1209. The procedure 1201 can repeat.

The procedure 1201 can provide for receiving a datum to be encoded 1203. For example, a bit from data to be encoded can be input from a component or another procedure. If desired, the data to be encoded can be received as, e.g., a bit stream, a parameter, a table, or the like, and broken decomposed into individual datum, e.g., each bit.

The procedure 1201 can provide for encoding the datum for position 1205. The datum can be encoded as described previously, so that a pulse in the output signal is in the correct position.

The procedure 1201 can provide for encoding the datum for phase 1207. The encoding of a datum to reflect phase has been described previously. The encoding of the datum for pulse and position can utilize the same encoding process. The pulse and position can be based on different output parameters of the encoding process. Optionally, as described above, a second pulse can be provided in the signal to reflect the same datum.

The procedure 1201 can provide for outputting a signal with the encoded data 1209. For example, an output of the procedure as ones and zeros can be provided to, e.g., a pulse forming network, which can control the pulses to be transmitted from a transmitter or transceiver.

Accordingly, one or more embodiments can provide a method of providing encoded data. The method can comprise receiving a datum to be encoded. Further, the method can comprise, responsive to the datum, encoding the datum into a pulse of a waveform to reflect a position corresponding to the datum, and encoding the datum into the pulse to reflect a phase corresponding to the datum. The method moreover can comprise outputting an output signal representative of the waveform.

Referring now to FIG. 13, a flow chart illustrating an exemplary procedure 1301 for demodulating encoded data in accordance with various exemplary and alternative exemplary embodiments will be discussed and described. The procedure can advantageously be implemented on, for example, a processor of a controller, described in connection with FIG. 2 or other apparatus appropriately arranged.

In overview, the procedure 1301 for demodulating encoded data, according to one or more embodiments, can include receiving a signal with encoded data 1301, demodulating the data to reflect the position and phase of a pulse 1305, determining the original data represented by the pulse 1307, and outputting a signal representative of the data 1309. The procedure 1301 can repeat.

The procedure 1301 can provide for receiving a signal with encoded data 1301, where the encoded data has been formatted in accordance with one or more embodiments. The signal can be received from, e.g., a receiver or transceiver in accordance with known techniques and the received signal being provided, e.g., as data reflecting the signal, for further processing.

The procedure 1301 can provide for demodulating the data to reflect the position and phase of a pulse 1305. The data can be demodulated as described previously, to determine the position and phase of the pulse.

The procedure 1301 can provide for determining the original data represented by the pulse 1307. For example, an estimation can be made of the position, phase, and/or differential phase of the pulse. Optionally, more than one estimation can be made.

The procedure 1301 can provide for outputting a signal representative of the data 1309. The decoded information can be output, e.g., as a signal, data stream of digital data, table of digital information, output digital parameters, or the like. Based on one or more of these estimations, an estimate of the demodulated data can be made.

Accordingly, one or more embodiments can provide for a method of demodulating encoded data. The method can comprise receiving a signal, the received signal comprising data representative of a non-coherent waveform and a coherent waveform. The method further can comprise, responsive to the received signal, demodulating the data to reflect a position of a pulse of the waveform and a phase of the waveform. The method further can comprise determining, responsive to the pulse and the phase, information represented by the data. Further, the method can comprise outputting an output signal representative of the information.

It should be noted that the term communication device may be used herein to denote a wired device, for example a high speed modem, an xDSL type modem, a wireline UWB device, and the like, and a wireless device, and typically a wireless device that may be used with a public network, for example in accordance with a service agreement, or within a private network such as an enterprise network or an ad hoc network. Examples of such communication devices include a cellular handset or device, television apparatus, personal digital assistants, personal assignment pads, and personal computers equipped for wireless operation, and the like, or equivalents thereof, provided such devices are arranged and constructed for operation in connection with wired or wireless communication.

The wireless communication devices of interest may have short range wireless communications capability normally referred to as WLAN (wireless local area network) capabilities, such as IEEE 802.11, Bluetooth, WPAN (wireless personal area network) or Hiper-Lan and the like using, for example, CDMA, frequency hopping, OFDM (orthogonal frequency division multiplexing) or TDMA (Time Division Multiple Access) access technologies and one or more of various networking protocols, such as TCP/IP (Transmission Control Protocol/Internet Protocol), UDP/UP (Universal Datagram Protocol/Universal Protocol), IPX/SPX (Inter-Packet Exchange/Sequential Packet Exchange), Net BIOS (Network Basic Input Output System) or other protocol structures. Alternatively the wireless communication devices of interest may be connected to a LAN using protocols such as TCP/IP, UDP/UP, IPX/SPX, or Net BIOS via a hardwired interface such as a cable and/or a connector.

The communication devices of particular interest are those providing or facilitating voice communications services or data or messaging services over ultra wideband networks, cellular wide area networks (WANs), such as conventional two way systems and devices, various cellular phone systems including analog and digital cellular, CDMA (code division multiple access) and variants thereof, GSM (Global System for Mobile Communications), GPRS (General Packet Radio System), 2.5G and 3G systems such as UMTS (Universal Mobile Telecommunication Service) systems, Internet Protocol (IP) Wireless Wide Area Networks like 802.16, 802.20 or Flarion, integrated digital enhanced networks and variants or evolutions thereof.

This disclosure is intended to explain how to fashion and use various embodiments in accordance with the invention rather than to limit the true, intended, and fair scope and spirit thereof. The invention is defined solely by the appended claims, as they may be amended during the pendency of this application for patent, and all equivalents thereof. The foregoing description is not intended to be exhaustive or to limit the invention to the precise form disclosed. Modifications or variations are possible in light of the above teachings. The embodiment(s) was chosen and described to provide the best illustration of the principles of the invention and its practical application, and to enable one of ordinary skill in the art to utilize the invention in various embodiments and with various modifications as are suited to the particular use contemplated. All such modifications and variations are within the scope of the invention as determined by the appended claims, as may be amended during the pendency of this application for patent, and all equivalents thereof, when interpreted in accordance with the breadth to which they are fairly, legally, and equitably entitled.

What is claimed is:

1. A method of providing encoded data, comprising:
receiving a datum to be encoded;
responsive to the datum, encoding the datum into a pulse of a waveform to reflect a position corresponding to the datum, and encoding the datum into the pulse to reflect a phase corresponding to the datum; and
outputting an output signal representative of the waveform.

2. The method of claim 1, further comprising transmitting the output signal over a transmitter.

3. The method of claim 1, wherein the encoding of the datum into the pulse to reflect the position further comprises encoding for pulse position modulation or on-off keying.

4. The method of claim 1, wherein the encoding of the datum into the pulse to reflect the phase further comprises utilizing a convolutional encoding process.

5. The method of claim 4, wherein the convolutional encoding is systematic.

6. The method of claim 1, wherein the encoding of the datum into the pulse reflecting the position utilizes a convolutional encoding process.

7. The method of claim 1, wherein the waveform further includes at least another pulse, wherein the other pulse is delayed from the first pulse by a pre-determined time.

8. The method of claim 7, wherein a position of the first pulse and the other pulse is determined by the datum according to a convolutional encoding process.

9. The method of claim 7, wherein a differential phase of the other pulse is determined by the datum according to a coherent coding process.

10. The method of claim 1, wherein the method is performed in an impulse radio transmitter.

11. A method of demodulating encoded data, comprising:
receiving a signal, the received signal comprising data representative of a non-coherent waveform and a coherent waveform;
responsive to the received signal, demodulating the data to reflect a position of a pulse of the waveform and a phase of the waveform;
determining, responsive to the pulse and the phase, information represented by the data; and
outputting an output signal representative of the information.

12. The method of claim 11, further comprising utilizing at least one of the position and the phase to further estimate the information.

13. The method of claim 11, further comprising utilizing a differential phase to estimate the information.

14. The method of claim 11, wherein the determining further comprises utilizing Viterbi decoding utilizing at least one of the position, the phase and the differential phase.

15. The method of claim 11, wherein the method is performed in an impulse radio receiver.

16. A communication device for transmitting data, comprising:
a processor, the processor being configured to facilitate, responsive to receipt of a datum, first determining a position for a pulse in a waveform corresponding to the datum and second determining a phase for the pulse in the waveform corresponding to the datum; and responsive to the first determining and second determining, providing a data stream representative of the waveform having the pulse of the phase in the position to a transmitter; and
a transmitter, responsive to receipt of the data stream, configured to transmit the signal.

17. The communication device of claim 16, wherein the processor is further configured to facilitate encoding the datum into the pulse to reflect the phase utilizing a convolutional encoding process.

18. The communication device of claim 16, wherein the processor is further configured to encode the datum into the pulse to reflect the position utilizing encoding for pulse position modulation or on-off keying.

19. The communication device of claim 16, wherein the transmitter is an impulse radio transmitter.

20. The communication device of claim 16, wherein the waveform further includes at least another pulse, wherein the processor is further configured to facilitate determining the other pulse including delaying the other pulse from the first pulse by a pre-determined time.
